(19) United States
(12) Patent Application Publication
(10) Pub. No.: US 2025/0069681 A1
(43) Pub. Date: Feb. 27, 2025

(54) MEMORY

(71) Applicant: CXMT CORPORATION, Hefei (CN)

(72) Inventor: Jia WANG, Hefei (CN)

(21) Appl. No.: 18/945,588

(22) Filed: Nov. 13, 2024

Related U.S. Application Data
(63) Continuation of application No. PCT/CN2023/097742, filed on Jun. 1, 2023.

(30) Foreign Application Priority Data
Mar. 3, 2023 (CN) 202310194643.3

(51) Int. Cl. G11C 29/56

(52) U.S. Cl. CPC G11C 29/56008; G11C 29/56016; G11C 2029/5602

(57) ABSTRACT

A memory is disclosed. An input terminal of a compression circuit receives read data transmitted through transmission paths of multiple data input/output pins, and the compression circuit separately compresses the read data transmitted through the transmission paths of the data input/output pins. A first input terminal of a data input/output selector is connected to an output terminal of the compression circuit, and the data input/output selector receives multiple pieces of compressed data, and is configured to: in a test mode, transmit the multiple pieces of compressed data to any one of the multiple data input/output pins.

The present disclosure claims priority to Chinese Patent Application No. 202310194643.3, filed with the China National Intellectual Property Administration on Mar. 3, 2023 and entitled “MEMORY”, which is incorporated herein by reference in its entirety.

### TECHNICAL FIELD

The present disclosure relates to the field of memory technologies, and in particular, to a memory.

### BACKGROUND

With widespread application of various memories, e.g., widely applied dynamic random access memories (DRAM), in an actual application, a packaged memory needs to be tested to ensure product reliability.

Therefore, how to improve test efficiency of the memory becomes a problem that needs to be considered.

### SUMMARY

Embodiments of the present disclosure provide a memory, to improve test efficiency of the memory.

According to some embodiments, the present disclosure provides a memory, including:
a compression circuit, an input terminal of the compression circuit receiving read data transmitted through transmission paths of multiple data input/output pins, and the compression circuit being configured to separately compress the read data transmitted through the transmission paths of the data input/output pins, to obtain multiple pieces of compressed data; and
a data input/output selector, a first input terminal of the data input/output selector being connected to an output terminal of the compression circuit, and the data input/output selector receiving the multiple pieces of compressed data and being configured to: in a test mode, transmit the multiple pieces of compressed data to a target data input/output pin,
the target data input/output pin being any one of the multiple data input/output pins.

In the memory provided in the present disclosure, the input terminal of the compression circuit receives the read data transmitted through the transmission paths of the multiple data input/output pins, and the compression circuit separately compresses the read data transmitted through the transmission paths of the data input/output pins, to obtain the multiple pieces of compressed data. The first input terminal of the data input/output selector is connected to the output terminal of the compression circuit, the data input/output selector receives the multiple pieces of compressed data output by the compression circuit, and in the test mode, the data input/output selector transmits the multiple pieces of compressed data to any one of the multiple data input/output pins in the memory, so that only one data input/output pin needs to be utilized during a test, thereby reducing the quantity of utilized data input/output pins, increasing the quantity of simultaneously tested memories, and improving test efficiency.

### BRIEF DESCRIPTION OF DRAWINGS

The accompanying drawings herein, which are incorporated in and constitute a part of the specification, illustrate embodiments consistent with the present disclosure, and serve to explain the principles of the embodiments of the present disclosure together with the specification.

FIG. 1 is a schematic diagram of read and write data transmission according to an embodiment of the present disclosure;

FIG. 2 is an example structural diagram of a memory according to an embodiment of the present disclosure;

FIG. 3 is an example structural diagram of a memory according to another embodiment of the present disclosure; and

FIG. 4 is a schematic diagram of read data transmission according to an embodiment of the present disclosure.

The foregoing accompanying drawings already show clear embodiments of the present disclosure, which are described in more detail below. These accompanying drawings and text descriptions are not intended to limit the scope of the concept of the present disclosure in any manner, but to describe the concept of the present disclosure for a person skilled in the art with reference to specific embodiments.

### DESCRIPTION OF EMBODIMENTS

Example embodiments are described in detail herein, and examples thereof are shown in the accompanying drawings. When the following descriptions relate to the accompanying drawings, unless otherwise indicated, the same numbers in different accompanying drawings represent the same or similar elements. Implementations described in the following example embodiments do not represent all implementations consistent with the present disclosure. On the contrary, they are merely examples of apparatuses and methods that are consistent with some aspects of the present disclosure as detailed in the appended claims.

The terms “include” and “have” in the present disclosure are utilized to denote an open-ended inclusion, and indicate that other elements/components/etc. can be present in addition to the elements/components/etc. listed. The terms “first”, “second”, and the like are utilized only for labeling purposes, and do not limit the quantity of objects thereof. In addition, different elements and areas in the accompanying drawings are merely shown schematically. Therefore, the present disclosure is not limited to a size or a distance shown in the accompanying drawings.

The technical solutions of the present disclosure are described below in detail through specific embodiments. The following several specific embodiments may be combined with each other. A same or similar concept or process may not be described in some embodiments. The embodiments of the present disclosure are described below with reference to the accompanying drawings.

Table 1 is an example diagram of a pin architecture of a memory according to an embodiment of the present disclosure. As shown in Table 1, the memory includes multiple pins, and the multiple pins may be classified into power pins, data/address pins, and control command pins.

TABLE 1

| Pin number | Pin name |
|---|---|
| 1 | VDD2H |
| 2 | VSS |
| 3 | VDD1 |
| 4 | VDD2H |
| 5 | VDD2L |
| 6 | VSS |
| 7 | VDD2H |
| 8 | VSS |
| 9 | DQ8 |
| 10 | VDDQ |
| 11 | DQ9 |
| 12 | VSS |
| 13 | DQ10 |
| 14 | VDDQ |
| 15 | DQ11 |
| 16 | VSS |
| 17 | RDQS1_t |
| 18 | RDQS1_c |
| 19 | VDDQ |
| 20 | VDD2H |
| 21 | WCK1_c |
| 22 | WCK1_t |
| 23 | VSS |
| 24 | VDD2L |
| 25 | VDDQ |
| 26 | DMI1 |
| 27 | VSS |
| 28 | DQ12 |
| 29 | VDDQ |
| 30 | DQ13 |
| 31 | VSS |
| 32 | DQ14 |
| 33 | VDDQ |
| 34 | DQ15 |
| 35 | VSS |
| 36 | VDD2H |
| 37 | RESET_n |
| 38 | VDD2L |
| 39 | VSS |
| 40 | CA6 |
| 41 | CA5 |
| 42 | VDD2H |
| 43 | CA4 |
| 44 | CA3 |
| 45 | VSS |
| 46 | CK_c |
| 47 | CK_t |
| 48 | VDD2H |
| 49 | CS |
| 50 | CA2 |
| 51 | VSS |
| 52 | CA1 |
| 53 | CA0 |
| 54 | VDD2H |
| 55 | VDD2L |
| 56 | VSS |
| 57 | ZQ |
| 58 | VDDQ |
| 59 | VDD2H |
| 60 | VSS |
| 61 | DQ7 |
| 62 | VDDQ |
| 63 | DQ6 |
| 64 | VSS |
| 65 | DQ5 |
| 66 | VDDQ |
| 67 | DQ4 |
| 68 | VSS |
| 69 | DMI0 |
| 70 | VDDQ |
| 71 | VDD2L |
| 72 | VSS |
| 73 | WCK0_t |
| 74 | WCK0_c |
| 75 | VDD2H |
| 76 | VDDQ |
| 77 | RDQS0_c |
| 78 | RDQS0_t |
| 79 | VSS |
| 80 | DQ3 |
| 81 | VDDQ |
| 82 | DQ2 |
| 83 | VSS |
| 84 | DQ1 |
| 85 | VDDQ |
| 86 | DQ0 |
| 87 | VSS |
| 88 | VDD2H |
| 89 | VSS |
| 90 | VDD2L |
| 91 | VDD2H |
| 92 | VDD1 |
| 93 | VSS |
| 94 | VDD2H |

The power pins may include a VDD1 pin, a VDD2H pin, a VDD2L pin, and a VDDQ pin. VDD1 is received by the VDD1 pin to supply power to a memory core. VDD2H is received by the VDD2H pin to supply power to the memory core. VDD2L is received by the VDD2L pin to supply power to the memory core, too. VDDQ is received by the VDDQ pin to supply power to an I/O buffer. In an actual application, there may be three voltages in the memory, which are respectively VDD1, VDD2, and VDDQ. VDD2 may include VDD2H and VDD2L. VDD1 and VDD2 represent operating voltages of the memory core, and VDD1 and VDD2 have different voltage values. VDD2H indicates a relatively high voltage value, VDD2L indicates a relatively low voltage value, VDDQ indicates a high-quality voltage subjected to noise filtering, and anti-interference strength of VDDQ is large.

The data/address pins may include DQ0 to DQ15 pins and CA0 to CA6 pins. In an actual application, the memory includes a memory array, and the memory array includes multiple memory cells, and each memory cell has a corresponding row and column. During a read operation or a write operation, a row and a column of the memory array on which reading or writing is to be performed need to be first specified to determine a memory cell on which reading or writing is to be performed. Read addresses or write addresses may be received by the CA0 to CA6 pins. The read address includes a row and a column of the memory array on which reading is to be performed, and the write address includes a row and a column of the memory array on which writing is to be performed. Write data may be received and read data may be output by the DQ0 to DQ15 pins. During a read operation, data read from the memory cell is output by the DQ0 to DQ15 pins. During a write operation, data to be written into the memory cell is received by the DQ0 to DQ15 pins.

The control command pins may include WCK pins, RDQS pins (also referred to as read strobe pins), DMI pins, CK pins, and the like. The WCK pins include a WCK1_t pin, a WCK1_c pin, a WCK0_t pin, and a WCK0_c pin, the RDQS pins include an RDQS1_t pin, an RDQS1_c pin, an RDQS0_t pin, and an RDQS0_c pin, the DMI pins include a DMI0 pin and a DMI1 pin, and the CK pins include a CK_t pin and a CK_c pin. WCK1_t is received by the WCK1_t pin, WCK1_c is received by the WCK1_c pin, WCK0_t is received by the WCK0_t pin, and WCK0_c is received by the WCK0_c pin. RDQS1_t is received by the RDQS1_t pin, RDQS1_c is received by the RDQS1_c pin, RDQS0_t is received by the RDQS0_t pin, and RDQS0_c is received by the RDQS0_c pin. DMI0 is received by the DMI0 pin, and DMI1 is received by the DMI1 pin. CK_t is received by the CK_t pin, and CK_c is received by the CK_c pin.

WCK1_t, WCK1_c, WCK0_t, and WCK0_c represent write clocks, and the write clocks are configured to sample the write data received by the DQ0 to DQ15 pins. In an actual application, WCK1_t and WCK1_c are configured to sample write data received by DQ8 to DQ15 pins, and WCK0_t and WCK0_c are configured to sample write data received by DQ0 to DQ7 pins. WCK1_t, WCK1_c, WCK0_t, and WCK0_c may run at twice or four times a frequency of CK_t/CK_c to increase a sampling rate. RDQS1_t, RDQS1_c, RDQS0_t, and RDQS0_c represent read clocks, and are also referred to as read strobe signals. The read clocks are configured to sample the read data output by the DQ0 to DQ15 pins. In an actual application, RDQS1_t and RDQS1_c are configured to sample read data output by the DQ8 to DQ15 pins, and RDQS0_t and RDQS0_c are configured to sample read data output by the DQ0 to DQ7 pins.

DMI1 and DMI0 represent data mask (DM) signals, and the data mask signals are configured to mask the write data received by the DQ0 to DQ15 pins, to determine write data that is to be written into the memory cell. In an actual application, DMI1 is configured to mask the write data received by the DQ8 to DQ15 pins, and DMI0 is configured to mask the write data received by the DQ0 to DQ7 pins.

CK_t and CK_c represent command address clocks, and the command address clocks are configured to sample the read address or the write address. In an actual application, all commands, addresses, and input control signals are sampled at an intersection of a rising edge of CK_t and a falling edge of CK_c.

The control command pins may further include a ZQ pin, a RESET pin, a CS pin, and the like. ZQ is received by the ZQ pin. ZQ represents a calibration signal, and the calibration signal is configured to calibrate output drive strength. RESET_n is received by the RESET_n pin. RESET_n represents a reset signal, and the reset signal is configured to reset the memory to a default state during initialization. CS is received by the CS pin. CS represents a chip select signal, and the chip select signal is configured to select a target die.

It should be noted that pins related to data input/output include the DQ0 to DQ15 pins, the WCK1_t pin, the WCK1_c pin, the WCK0_t pin, the WCK0_c pin, the RDQS1_t pin, the RDQS1_c pin, the RDQS0_t pin, the RDQS0_c pin, the DMI1 pin, and the DMI0 pin. It can be learned that 26 pins are related to data input/output.

In an actual application, to ensure reliability of a memory product, the memory needs to be tested after being packaged. A memory test involves writing and reading on the memory, and the writing and the reading on the memory depend on pins of the memory.

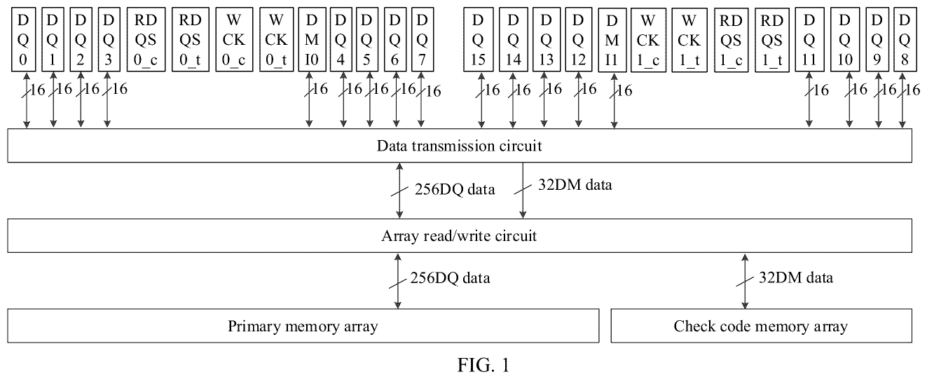

FIG. 1 is an example diagram of read and write data transmission according to an embodiment of the present disclosure. Taking a write scenario as an example, 16-bit write data is received by each of the DQ0 to DQ15 pins, WCK0_t is received by the WCK0_t pin, and WCK0_c is received by the WCK0_c pin. WCK0_t and WCK0_c are configured to sample the write data received by the DQ0 to DQ7 pins. WCK1_t is received by the WCK1_t pin, and WCK1_c is received by the WCK1_c pin. WCK1_t and WCK1_c are configured to sample the write data received by the DQ8 to DQ15 pins.

As shown in FIG. 1, 16-bit write data is received by each DQ pin, and data of a total of 256 bits is received by the DQ0 to DQ15 pins and stored in a primary memory array. 16-bit check code data is received by each of the DMI0 and the DMI1 and stored in a check code memory array.

Taking a read scenario as an example, an array read/write circuit reads data from the primary memory array and reads the check code data from the check code memory array, and transmits the read data to a data transmission circuit. The data transmission circuit transmits the read data to a DQ pin, and transmits the check code data to a DMI pin. As shown in FIG. 1, the array read/write circuit reads the 256-bit data from 256 memory cells of the primary memory array, and transmits the 256-bit data to the data transmission circuit. The data transmission circuit transmits data of every 16 bits to each of the DQ0 to DQ15 pins. Subsequently, RDQS0_t is received by the RDQS0_t pin, and RDQS0_c is received by the RDQS0_c pin. RDQS0_t and RDQS0_c are configured to sample the read data output by the DQ0 to DQ7 pins. RDQS1_t is received by the RDQS1_t pin, and RDQS1_c is received by the RDQS1_c pin. RDQS1_t and RDQS1_c are configured to sample the read data output by the DQ8 to DQ15 pins. The array read/write circuit reads 32-bit check code data from the check code memory array, and respectively transmits the 32-bit check code data to the DMI0 pin and the DMI1 pin, to be specific, 16-bit check code data is received by the DMI0 pin, and 16-bit check code data is received by the DMI1 pin.

In a memory test process, if data transmission, signal transmission, or the like is performed with all pins, the quantity of simultaneously tested memories is limited, and test efficiency is reduced.

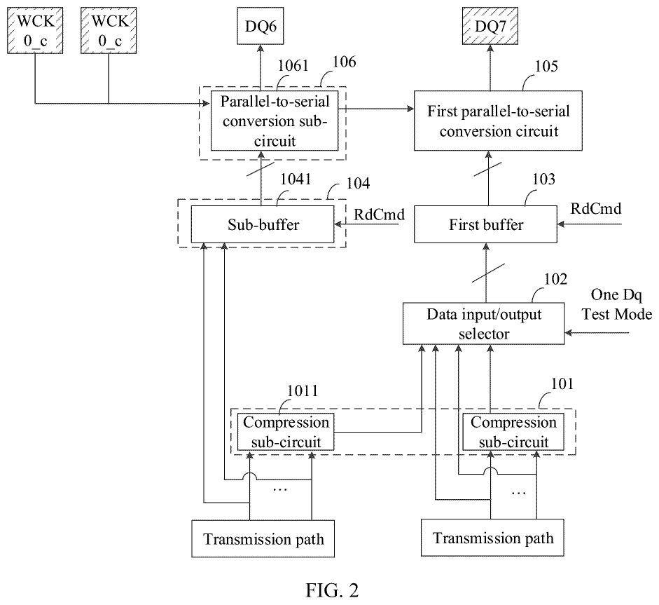

FIG. 2 is an example structural diagram of a memory according to an embodiment of the present disclosure. The memory provided in this embodiment is configured to reduce the quantity of utilized pins of the memory in a test process. As shown in FIG. 2, the memory includes a compression circuit 101 and a data input/output selector 102. An input terminal of the compression circuit 101 receives read data transmitted through transmission paths of multiple data input/output pins, and the compression circuit 101 is configured to separately compress the read data transmitted through the transmission paths of the data input/output pins, to obtain multiple pieces of compressed data. A first input terminal of the data input/output selector 102 is connected to an output terminal of the compression circuit 101, the data input/output selector receives the multiple pieces of compressed data, and the data input/output selector 102 is configured to: in a test mode, transmit the multiple pieces of compressed data to a target data input/output pin. The target data input/output pin is any one of the multiple data input/output pins. In the test mode, the multiple pieces of compressed data are transmitted to any data input/output pin of the memory after the read data transmitted through the transmission paths of the data input/output pins is separately compressed. Therefore, in the test mode, data needs to be output with only one data input/output pin, so that only one data input/output pin needs to be utilized during a test, thereby reducing the quantity of utilized data input/output pins, increasing the quantity of simultaneously tested memories, and improving test efficiency.

The transmission paths of the data input/output pins are paths for transmitting data read from memory cells to the data input/output pins, e.g., the array read/write circuit and the data transmission circuit in the foregoing embodiment.

In an actual application, the memory provided in this embodiment may be applied to tests of various memory chips. For example, the memory may be applied to, including but not limited to, a low power double data rate synchronous dynamic random access memory (LPDDR SDRAM), e.g., LPDDR5. The memory in this embodiment may be considered as a device under test (DUT).

In this embodiment, in the test mode, each bit of data in write data received by the target data input/output pin may be transmitted to a transmission path corresponding to each data input/output pin, so that the same data is written into multiple memory cells. Therefore, write data transmitted through all transmission paths corresponding to any data input/output pin may be the same. When read data transmitted through transmission paths corresponding to any data input/output pin is the same, the compression circuit receives read data transmitted through transmission paths corresponding to each data input/output pin, and compresses the read data to obtain compressed data corresponding to the data input/output pin. If compressed data corresponding to each data input/output pin indicates that all bits of data in read data transmitted through transmission paths corresponding to the data input/output pin are the same, it may be determined with the multiple pieces of compressed data that the memory is normal. If compressed data corresponding to each of some data input/output pins indicates that a part of data in read data transmitted through transmission paths corresponding to the data input/output pin is different, it may be determined with the multiple pieces of compressed data that the memory is faulty, and some memory cells may fail or some transmission paths may be problematic.

The compression circuit 101 may include multiple compression sub-circuits 1011, and an input terminal of each compression sub-circuit 1011 receives read data transmitted through transmission paths of one data input/output pin. Each data input/output pin includes multiple transmission paths, and 1-bit data read from one memory cell is transmitted through each transmission path. Therefore, read data transmitted through transmission paths of one data input/output pin may include multiple pieces of parallel 1-bit data. After receiving read data transmitted through transmission paths of a corresponding data input/output pin, each compression sub-circuit 1011 compresses the read data transmitted through the transmission paths of the corresponding data input/output pin, to obtain a corresponding compression result. Because each compression result is obtained by compressing read data of multiple memory cells, each compression result may indicate whether deficiency exists in the corresponding memory cells.

In an actual application, each compression sub-circuit may include an XOR gate and a NOT gate. As an input terminal of the corresponding compression sub-circuit, an input terminal of the XOR gate receives read data transmitted through transmission paths of one data input/output pin, an output terminal of the XOR gate is connected to an input terminal of the NOT gate, and an output terminal of the NOT gate serves as an output terminal of the corresponding compression sub-circuit, to compress read data transmitted through transmission paths of a corresponding data input/output pin, so as to obtain 1-bit compressed data.

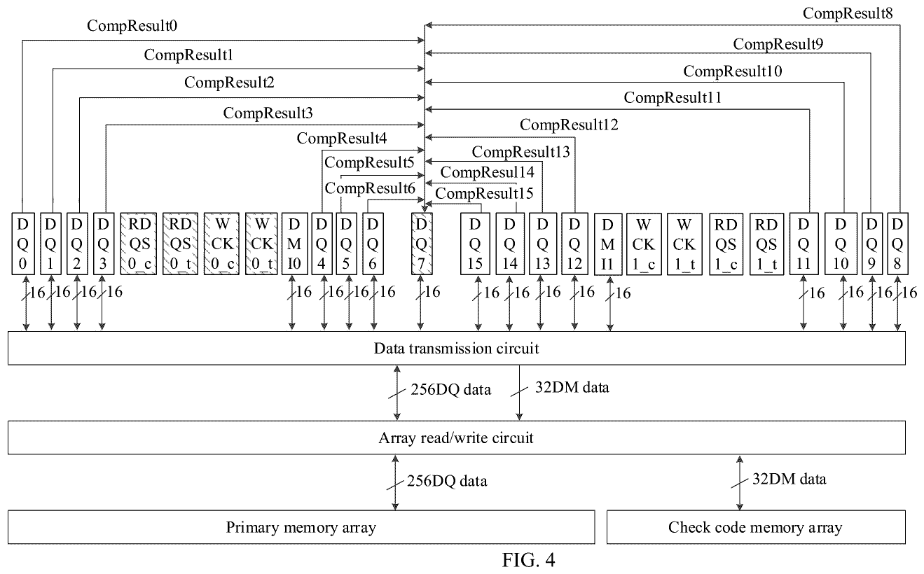

For example, FIG. 2 is an example diagram of read data transmission according to an embodiment of the present disclosure. FIG. 2 shows only the DQ6 pin and the DQ7 pin. It may be understood that the memory includes but is not limited to the DQ6 pin and the DQ7 pin. As shown in FIG. 2 and FIG. 4, the memory may include the DQ0 to DQ15 pins. First compressed data CompResult0 is obtained after read data transmitted through transmission paths of the DQ0 pin is compressed. Second compressed data CompResult1 is obtained after read data transmitted through transmission paths of the DQ1 pin is compressed. Third compressed data CompResult2 is obtained after read data transmitted through transmission paths of the DQ2 pin is compressed. Fourth compressed data CompResult3 is obtained after read data transmitted through transmission paths of the DQ3 pin is compressed. Fifth compressed data CompResult4 is obtained after read data transmitted through transmission paths of the DQ4 pin is compressed. Sixth compressed data CompResult5 is obtained after read data transmitted through transmission paths of the DQ5 pin is compressed. Seventh compressed data CompResult6 is obtained after read data transmitted through transmission paths of the DQ6 pin is compressed. Eighth compressed data CompResult7 is obtained after read data transmitted through transmission paths of the DQ7 pin is compressed. Ninth compressed data CompResult8 is obtained after read data transmitted through transmission paths of the DQ8 pin is compressed. Tenth compressed data CompResult9 is obtained after read data transmitted through transmission paths of the DQ9 pin is compressed. Eleventh compressed data CompResult10 is obtained after read data transmitted through transmission paths of the DQ10 pin is compressed. Twelfth compressed data CompResult11 is obtained after read data transmitted through transmission paths of the DQ11 pin is compressed. Thirteenth compressed data CompResult12 is obtained after read data transmitted through transmission paths of the DQ12 pin is compressed. Fourteenth compressed data CompResult13 is obtained after read data transmitted through transmission paths of the DQ13 pin is compressed. Fifteenth compressed data CompResult14 is obtained after read data transmitted through transmission paths of the DQ14 pin is compressed. Sixteenth compressed data CompResult15 is obtained after read data transmitted through transmission paths of the DQ15 pin is compressed.

Correspondingly, when all bits of data in the read data transmitted through the transmission paths of the DQ0 pin are the same, the first compressed data CompResult0 is 1; otherwise, the first compressed data CompResult0 is 0. When all bits of data in the read data transmitted through the transmission paths of the DQ1 pin are the same, the second compressed data CompResult1 is 1; otherwise, the second compressed data CompResult1 is 0. When all bits of data in the read data transmitted through the transmission paths of the DQ2 pin are the same, the third compressed data CompResult2 is 1; otherwise, the third compressed data CompResult2 is 0. When all bits of data in the read data transmitted through the transmission paths of the DQ3 pin are the same, the fourth compressed data CompResult3 is 1; otherwise, the fourth compressed data CompResult3 is 0. When all bits of data in the read data transmitted through the transmission paths of the DQ4 pin are the same, the fifth compressed data CompResult4 is 1; otherwise, the fifth compressed data CompResult4 is 0. When all bits of data in the read data transmitted through the transmission paths of the DQ5 pin are the same, the sixth compressed data CompResult5 is 1; otherwise, the sixth compressed data CompResult5 is 0. When all bits of data in the read data transmitted through the transmission paths of the DQ6 pin are the same, the seventh compressed data CompResult6 is 1; otherwise, the seventh compressed data CompResult6 is 0. When all bits of data in the read data transmitted through the transmission paths of the DQ7 pin are the same, the eighth compressed data CompResult7 is 1; otherwise, the eighth compressed data CompResult7 is 0. When all bits of data in the read data transmitted through the transmission paths of the DQ8 pin are the same, the ninth compressed data CompResult8 is 1; otherwise, the ninth compressed data CompResult8 is 0. When all bits of data in the read data transmitted through the transmission paths of the DQ9 pin are the same, the tenth compressed data CompResult9 is 1; otherwise, the tenth compressed data CompResult9 is 0. When all bits of data in the read data transmitted through the transmission paths of the DQ10 pin are the same, the eleventh compressed data CompResult10 is 1; otherwise, the eleventh compressed data CompResult10 is 0. When all bits of data in the read data transmitted through the transmission paths of the DQ11 pin are the same, the twelfth compressed data CompResult11 is 1; otherwise, the twelfth compressed data CompResult11 is 0. When all bits of data in the read data transmitted through the transmission paths of the DQ12 pin are the same, the thirteenth compressed data CompResult12 is 1; otherwise, the thirteenth compressed data CompResult12 is 0. When all bits of data in the read data transmitted through the transmission paths of the DQ13 pin are the same, the fourteenth compressed data CompResult13 is 1; otherwise, the fourteenth compressed data CompResult13 is 0. When all bits of data in the read data transmitted through the transmission paths of the DQ14 pin are the same, the fifteenth compressed data CompResult14 is 1; otherwise, the fifteenth compressed data CompResult14 is 0. When all bits of data in the read data transmitted through the transmission paths of the DQ15 pin are the same, the sixteenth compressed data CompResult15 is 1; otherwise, the sixteenth compressed data CompResult15 is 0.

In some embodiments, the data input/output selector further includes a second input terminal, read data transmitted through transmission paths of the target data input/output pin is received by the second input terminal, and the read data transmitted through the transmission paths of the target data input/output pin may be further transmitted to the target data input/output pin by the data input/output selector in an operating mode. A read operation or a write operation may be performed in the operating mode. In this embodiment, in the test mode, the multiple pieces of compressed data may be transmitted to any data input/output pin of the memory by the memory after the read data transmitted through the transmission paths of the data input/output pins is separately compressed, so that only one data input/output pin needs to be utilized during a test, thereby reducing the quantity of utilized data input/output pins, increasing the quantity of simultaneously tested memories, and improving test efficiency. In the operating mode, the read data transmitted through the transmission paths of the target data input/output pin may be transmitted to the target data input/output pin, to ensure normal operation of the memory.

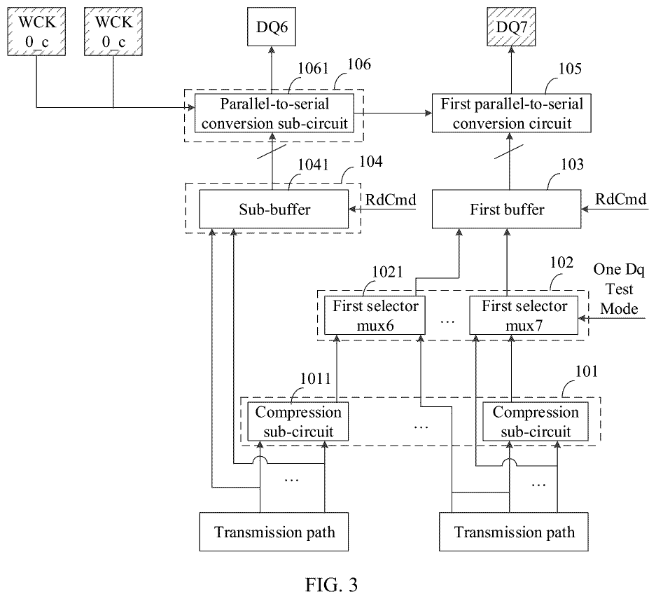

In some embodiments, as shown in FIG. 3, the data input/output selector 102 includes multiple first selectors 1021. Each first selector 1021 corresponds to one transmission path of the target data input/output pin. A first input terminal of each first selector 1021 receives compressed data corresponding to one data input/output pin, and a second input terminal of each first selector 1021 receives 1-bit read data in the read data transmitted through the transmission paths of the target data input/output pin. The target data input/output pin includes multiple transmission paths, and 1-bit data of one memory cell is transmitted through each transmission path. Therefore, each first selector 1021 receives 1-bit data of one memory cell transmitted through one transmission path of the target data input/output pin; and may further receive compressed data corresponding to one data input/output pin, in the operating mode, transmit, to the target data input/output pin, the received 1-bit data of one memory cell transmitted through one transmission path of the target data input/output pin, and in the test mode, transmit the compressed data of the corresponding data input/output pin to the target data input/output pin.

For example, the data input/output selector may include 16 first selectors, and the 16 first selectors are denoted as mux0 to mux 15. The read data transmitted through the transmission paths of the target data input/output pin includes 16-bit parallel data, respectively denoted as burst0 to burst 15.

For example, the target data input/output pin is the DQ7 pin. The first compressed data CompResult0 corresponding to the DQ0 pin is received by a first input terminal of mux0, and burst0 is received by a second input terminal of mux0. The second compressed data CompResult1 corresponding to the DQ1 pin is received by a first input terminal of mux1, and burst1 is received by a second input terminal of mux1. The third compressed data CompResult2 corresponding to the DQ2 pin is received by a first input terminal of mux2, and burst2 is received by a second input terminal of mux2. The fourth compressed data CompResult3 corresponding to the DQ3 pin is received by a first input terminal of mux3, and burst3 is received by a second input terminal of mux3. The fifth compressed data CompResult4 corresponding to the DQ4 pin is received by a first input terminal of mux4, and burst4 is received by a second input terminal of mux4. The sixth compressed data CompResult5 corresponding to the DQ5 pin is received by a first input terminal of mux5, and burst5is received by a second input terminal of mux5. The seventh compressed data CompResult6 corresponding to the DQ6 pin is received by a first input terminal of mux6, and burst6 is received by a second input terminal of mux6. The eighth compressed data CompResult7 corresponding to the DQ7 pin is received by a first input terminal of mux7, and burst7 is received by a second input terminal of mux7. The ninth compressed data CompResult8 corresponding to the DQ8 pin is received by a first input terminal of mux8, and burst8 is received by a second input terminal of mux8. The tenth compressed data CompResult9 corresponding to the DQ9 pin is received by a first input terminal of mux9, and burst9 is received by a second input terminal of mux9. The eleventh compressed data CompResult10 corresponding to the DQ10 pin is received by a first input terminal of mux10, and burst10 is received by a second input terminal of mux10. The twelfth compressed data CompResult11 corresponding to the DQ11 pin is received by a first input terminal of mux11, and burst11 is received by a second input terminal of mux11. The thirteenth compressed data CompResult12 corresponding to the DQ12 pin is received by a first input terminal of mux12, and burst12 is received by a second input terminal of mux12. The fourteenth compressed data CompResult13 corresponding to the DQ13 pin is received by a first input terminal of mux13, and burst13 is received by a second input terminal of mux13. The fifteenth compressed data CompResult14 corresponding to the DQ14 pin is received by a first input terminal of mux14, and burst14 is received by a second input terminal of mux14. The sixteenth compressed data CompResult15 corresponding to the DQ15 pin is received by a first input terminal of mux15, and burst15 is received by a second input terminal of mux15.

Correspondingly, in the test mode, the first compressed data CompResult0 corresponding to the DQ0 pin is transmitted to the DQ7 pin by mux0. The second compressed data CompResult1 corresponding to the DQ1 pin is transmitted to the DQ7 pin by mux1. The third compressed data CompResult2 corresponding to the DQ2 pin is transmitted to the DQ7 pin by mux2. The fourth compressed data CompResult3 corresponding to the DQ3 pin is transmitted to the DQ7 pin by mux3. The fifth compressed data CompResult4 corresponding to the DQ4 pin is transmitted to the DQ7 pin by mux4. The sixth compressed data CompResult5 corresponding to the DQ5 pin is transmitted to the DQ7 pin by mux5. The seventh compressed data CompResult6 corresponding to the DQ6 pin is transmitted to the DQ7 pin by mux6. The eighth compressed data CompResult7 corresponding to the DQ7 pin is transmitted to the DQ7 pin by mux7. The ninth compressed data CompResult8 corresponding to the DQ8 pin is transmitted to the DQ7 pin by mux8. The tenth compressed data CompResult9 corresponding to the DQ9 pin is transmitted to the DQ7 pin by mux9. The eleventh compressed data CompResult10 corresponding to the DQ10 pin is transmitted to the DQ7 pin by mux10. The twelfth compressed data CompResult11 corresponding to the DQ11 pin is transmitted to the DQ7 pin by mux11. The thirteenth compressed data CompResult12 corresponding to the DQ12 pin is transmitted to the DQ7 pin by mux12. The fourteenth compressed data CompResult13 corresponding to the DQ13 pin is transmitted to the DQ7 pin by mux13. The fifteenth compressed data CompResult14 corresponding to the DQ14 pin is transmitted to the DQ7 pin by mux14. The sixteenth compressed data CompResult15 corresponding to the DQ15 pin is transmitted to the DQ7 pin by mux15.

In the operating mode, burst0 is transmitted to the DQ7 pin by mux0, burst1 is transmitted to the DQ7 pin by mux1, burst2 is transmitted to the DQ7 pin by mux2, burst3 is transmitted to the DQ7 pin by mux3, burst4 is transmitted to the DQ7 pin by mux4, burst5 is transmitted to the DQ7 pin by mux5, burst6 is transmitted to the DQ7 pin by mux6, burst7 is transmitted to the DQ7 pin by mux7, burst8 is transmitted to the DQ7 pin by mux8, burst9 is transmitted to the DQ7 pin by mux9, burst10 is transmitted to the DQ7 pin by mux10, burst11 is transmitted to the DQ7 pin by mux11, burst12 is transmitted to the DQ7 pin by mux12, burst13 is transmitted to the DQ7 pin by mux13, burst14 is transmitted to the DQ7 pin by mux14, and burst15 is transmitted to the DQ7 pin by mux15.

In some embodiments, as shown in FIG. 2, the memory may further include a first buffer (output FIFO) 103. An input terminal of the first buffer 103 is connected to the data input/output selector 102, and the first buffer 103 can receive and store data output by the data input/output selector 102. It may be understood that multiple pieces of compressed data herein are multiple pieces of 1-bit data, and the read data is also multiple pieces of 1-bit data. Specifically, in the test mode, the multiple pieces of compressed data are output by the data input/output selector 102, and the first buffer 103 may store the multiple pieces of compressed data, and output the multiple pieces of compressed data after receiving a read command. In the operating mode, the read data transmitted through the transmission paths of the target data input/output pin is output by the data input/output selector 102, and the first buffer 103 may store the read data transmitted through the transmission paths of the target data input/output pin, and output, after receiving a read command, the read data transmitted through the transmission paths of the target data input/output pin.

In an actual application, during a read operation, one piece of serial data of multiple bits is usually output by the memory with one data input/output pin. Therefore, when multiple pieces of 1-bit parallel data are obtained from multiple memory cells, the multiple pieces of 1-bit data of the multiple memory cells may be first converted into one piece of serial data of multiple bits, and then the one piece of serial data of multiple bits may be output with the data input/output pin.

In some embodiments, the memory may further include a first parallel-to-serial conversion circuit 105. An input terminal of the first parallel-to-serial conversion circuit 105 is connected to the first buffer 103, and the first parallel-to-serial conversion circuit receives data output by the first buffer 103, performs parallel-to-serial conversion on the data output by the first buffer 103, and outputs data obtained through parallel-to-serial conversion to the target data input/output pin. Specifically, when receiving the multiple pieces of compressed data, the first parallel-to-serial conversion circuit 105 may convert the multiple pieces of compressed data into serial data, and transmit the serial data to the target data input/output pin; or when receiving the read data transmitted through the transmission paths of the target data input/output pin, the first parallel-to-serial conversion circuit may convert the read data transmitted through the transmission paths of the target data input/output pin into serial data, and transmit the serial data to the target data input/output pin, so that the target data input/output pin can receive the serial data corresponding to the multiple pieces of compressed data or the serial data corresponding to the read data transmitted through the transmission paths of the target data input/output pin.

In this example, in the test mode, the first parallel-to-serial conversion circuit 105 can sort the multiple pieces of compressed data in a sequence of the data input/output pins, to convert the multiple pieces of compressed data into serial data, thereby clearly obtaining a compression result of read data transmitted through transmission paths of each data input/output pin. Specifically, the first compressed data CompResult0 corresponding to the DQ0 pin, the second compressed data CompResult1 corresponding to the DQ1 pin, the third compressed data CompResult2 corresponding to the DQ2 pin, the fourth compressed data CompResult3 corresponding to the DQ3 pin, the fifth compressed data CompResult4 corresponding to the DQ4 pin, the sixth compressed data CompResult5 corresponding to the DQ5 pin, the seventh compressed data CompResult6 corresponding to the DQ6 pin, the eighth compressed data CompResult7 corresponding to the DQ7 pin, the ninth compressed data CompResult8 corresponding to the DQ8 pin, the tenth compressed data CompResult9 corresponding to the DQ9 pin, the eleventh compressed data CompResult10 corresponding to the DQ10 pin, the twelfth compressed data CompResult11 corresponding to the DQ11 pin, the thirteenth compressed data CompResult12 corresponding to the DQ12 pin, the fourteenth compressed data CompResult13 corresponding to the DQ13 pin, the fifteenth compressed data CompResult14 corresponding to the DQ14 pin, and the sixteenth compressed data CompResult15 corresponding to the DQ15 pin are sequentially sorted to obtain the serial data corresponding to the multiple pieces of compressed data.

In some embodiments, the multiple data input/output pins in the memory include the target data input/output pin and other data input/output pins, and the other data input/output pins may be understood as all data input/output pins other than the target data input/output pin in the multiple data input/output pins in the memory. In this case, the memory may further include a second buffer. An input terminal of the second buffer receives read data transmitted through transmission paths of the other data input/output pins, the second buffer can store the read data transmitted through the transmission paths of the other data input/output pins, and after receiving a read command, the second buffer can further output the read data transmitted through the transmission paths of the other data input/output pins. For example, if the target data input/output pin is the DQ7 pin, and the other data input/output pins are the DQ0 to DQ6 pins and the DQ8 to DQ15 pins, the second buffer can store read data transmitted through transmission paths of the DQ0 to DQ6 pins and the DQ8 to DQ15 pins, and after receiving the read command, output the read data transmitted through the transmission paths of the DQ0 to DQ6 pins and the DQ8 to DQ15 pins.

In this example, as shown in FIG. 3, the second buffer 104 may include multiple sub-buffers 1041. Each sub-buffer 1041 corresponds to one data input/output pin. An input terminal of each sub-buffer 1041 receives read data transmitted through transmission paths of one of the other data input/output pins, and the sub-buffer stores the read data transmitted through the transmission paths of the data input/output pin corresponding to the sub-buffer, and after a read command is received, outputs the read data transmitted through the transmission paths of the data input/output pin corresponding to the sub-buffer, to transmit, to a corresponding data input/output pin, read data transmitted through transmission paths of each of the other data input/output pins. It may be understood that the sub-buffer 1041 stores read data transmitted through transmission paths of only one data input/output pin, and the first buffer 103 stores the read data transmitted through the transmission paths of the target data input/output pin and compressed data corresponding to each data input/output pin.

In this example, in both the test mode and the operating mode, the read data transmitted through the transmission paths of the other data input/output pins may be transmitted to the second buffer; and only data output by the target data input/output pin is collected in the test mode, and data output by the target data input/output pin and the other data input/output pins is collected in the operating mode.

In some embodiments, the memory may include a second parallel-to-serial conversion circuit 106. An input terminal of the second parallel-to-serial conversion circuit 106 is connected to the second buffer 104, and the second parallel-to-serial conversion circuit performs parallel-to-serial conversion on the data output by the second buffer 104, and outputs data obtained through parallel-to-serial conversion to the other data input/output pins. Specifically, after receiving the read data transmitted through the transmission paths of the other data input/output pins, the second parallel-to-serial conversion circuit 106 can transmit, to the other data input/output pins, the read data transmitted through the transmission paths of the other data input/output pins, so that the read data transmitted through the transmission paths of the other data input/output pins can be transmitted by the other data input/output pins.

In this example, the second parallel-to-serial conversion circuit 106 includes multiple parallel-to-serial conversion sub-circuits 1061. An input terminal of each parallel-to-serial conversion sub-circuit 1061 is connected to one sub-buffer 1041, and each parallel-to-serial conversion sub-circuit 1061 receives data output by the corresponding sub-buffer 1041, performs parallel-to-serial conversion on the data output by the corresponding sub-buffer 1041, and outputs data obtained through parallel-to-serial conversion to one of the other data input/output pins, so that read data transmitted through transmission paths of each of the other data input/output pins can be output by the data input/output pin.

The first parallel-to-serial conversion circuit 105 may perform, based on clock signals (WCK0_t and WCK0_c), parallel-to-serial conversion on the multiple pieces of compressed data corresponding to the multiple data input/output pins, and output data obtained through parallel-to-serial conversion to the target data input/output pin; or perform parallel-to-serial conversion on the read data transmitted through the transmission paths of the target data input/output pin, and output data obtained through parallel-to-serial conversion to the target data input/output pin. The second parallel-to-serial conversion circuit 106 may perform, based on a clock signal, parallel-to-serial conversion on read data transmitted through transmission paths of each data input/output pin, and output data obtained through parallel-to-serial conversion to the corresponding data input/output pin.

In an actual application, the memory may include a WCK1_t pin, a WCK1_c pin, a WCK0_t pin, and a WCK0_c pin. Generally, WCK1_t received by the WCK1_t pin and WCK1_c received by the WCK1_c pin are configured to convert the read data transmitted through the transmission paths of the DQ8 to DQ15 pins into serial data, and WCK0_t received by the WCK0_t pin and WCK0_c received by the WCK0_c pin are configured to convert read data transmitted through transmission paths of the DQ0 to DQ7 pins into serial data. In this example, in the test mode, WCK0_t may be received by the WCK0_t pin, WCK0_c may be received by the WCK0_c pin, and WCK0_t and WCK0_c are configured to convert parallel data received by the DQ0 to DQ15 pins into serial data, to further reduce the quantity of utilized pins in the memory and improve test efficiency.

In some embodiments, as shown in FIG. 4, the memory further includes data mask pins. Check code data is received by the data mask pins. The memory checks, based on the check code data, the read data transmitted through the transmission paths of the multiple data input/output pins, in other words, checks, with the check code data received by the data mask pins, data read from a primary memory array.

In this example, the data mask pins may include a first data mask pin and a second data mask pin, the first data mask pin receives first check code data, and the second data mask pin receives second check code data. The memory checks, based on the first check code data, data transmitted through transmission paths of some of the multiple data input/output pins, and checks, based on the second check code data, data transmitted through transmission paths of the remaining data input/output pins in the multiple data input/output pins. It may be understood that the remaining data input/output pins are data input/output pins other than the some data input/output pins in the multiple data input/output pins.

In an actual application, the memory further includes data mask pins. The data mask pins may include a DMI0 pin and a DMI1 pin. During a write operation, generally, a data mask received by the DMI0 pin is configured to control whether serial data received by the DQ0 to DQ7 pins to be written into the primary memory array, and a data mask received by the DMI1 pin is configured to control whether serial data received by the DQ8 to DQ15 pins to be written into the primary memory array. During a read operation, the first check code data may be received by the DMI0 pin to check the read data transmitted through the transmission paths of the DQ0 to DQ7 pins, and the second check code data is received by the DMI1 pin to check the read data transmitted through the transmission paths of the DQ8 to DQ15 pins.

In an actual application, the memory may include an RDQS0_t pin, an RDQS0_c pin, an RDQS1_t pin, and an RDQS1_c pin. Generally, RDQS0_t received by the RDQS0_t pin and RDQS0_c received by the RDQS0_c pin are configured to sample the serial data output by the DQ0 to DQ7 pins, and RDQS1_t received by the RDQS1_t pin and RDQS1_c received by the RDQS1_c pin are configured to sample the serial data output by the DQ8 to DQ15 pins. In this example, in the test mode, the multiple pieces of compressed data are output with only one of the multiple data input/output pins, and therefore, multiple pieces of compressed data output by the data input/output pin may be sampled with RDQS0_t received by the RDQS0_t pin and RDQS0_c received by the RDQS0_c pin, so that the quantity of utilized pins in the memory in a test process is further reduced, and test efficiency is improved.

The memory provided in the embodiments of the present disclosure is described in detail above. The compression circuit compresses the read data transmitted through the transmission paths of the data input/output pins to obtain the compressed data, and in the test mode, outputs the multiple pieces of compressed data with the data input/output selector, so that only one data input/output pin needs to be utilized during a test, thereby reducing the quantity of utilized data input/output pins, increasing the quantity of simultaneously tested memories, and improving test efficiency.

A person skilled in the art can easily figure out other implementation solutions of the present disclosure after considering the specification and practice of the present disclosure herein. The present disclosure is intended to cover any variations, functions, or adaptive changes of the present disclosure. These variations, functions, or adaptive changes comply with general principles of the present disclosure, and include common knowledge or a conventional technical means in the art that is not disclosed in the present disclosure. The specification and embodiments are merely considered as examples, and the true scope and spirit of the present disclosure are pointed out in the following claims.

It should be understood that the present disclosure is not limited to the precise structures described above and shown in the accompanying drawings, and various modifications and changes may be made without departing from the scope thereof. The scope of the present disclosure is limited only by the appended claims.

What is claimed is:

1. A memory, comprising:
a compression circuit, an input terminal of the compression circuit receiving read data transmitted through transmission paths of a plurality of data input/output pins, and the compression circuit being configured to separately compress the read data transmitted through the transmission paths of the data input/output pins, to obtain a plurality of pieces of compressed data; and
a data input/output selector, a first input terminal of the data input/output selector being connected to an output terminal of the compression circuit, and the data input/output selector receiving the plurality of pieces of compressed data and being configured to: in a test mode, transmit the plurality of pieces of compressed data to a target data input/output pin,
the target data input/output pin being any one of the plurality of data input/output pins.

2. The memory according to claim 1, wherein when read data transmitted through all transmission paths of any data input/output pin is the same, the plurality of pieces of compressed data are configured to indicate that the memory is normal if compressed data corresponding to each data input/output pin indicates that all bits of data in read data transmitted through transmission paths corresponding to the data input/output pin are the same; or the plurality of pieces of compressed data are configured to indicate that the memory is faulty if compressed data corresponding to each of some data input/output pins indicates that a part of data in read data transmitted through transmission paths corresponding to the data input/output pin is different.

3. The memory according to claim 2, wherein the compression circuit comprises a plurality of compression sub-circuits, and an input terminal of each compression sub-circuit receives read data transmitted through transmission paths of one data input/output pin; and
each compression sub-circuit is configured to compress read data transmitted through transmission paths of a data input/output pin corresponding to the compression sub-circuit, to obtain corresponding compressed data.

4. The memory according to claim 3, wherein each compression sub-circuit comprises an XOR gate and a NOT gate; and
as an input terminal of the corresponding compression sub-circuit, an input terminal of the XOR gate receives read data transmitted through transmission paths of one data input/output pin, an output terminal of the XOR gate is connected to an input terminal of the NOT gate, and an output terminal of the NOT gate serves as an output terminal of the corresponding compression sub-circuit.

5. The memory according to claim 1, wherein a second input terminal of the data input/output selector receives read data transmitted through transmission paths of the target data input/output pin, and the data input/output selector is configured to transmit, to the target data input/output pin when the data input/output selector is in an operating mode, the read data transmitted through the transmission paths of the target data input/output pin.

6. The memory according to claim 5, wherein the data input/output selector comprises a plurality of first selectors, and each first selector corresponds to one transmission path of the target data input/output pin;
a first input terminal of each first selector receives compressed data corresponding to one data input/output pin, and a second input terminal of each first selector receives 1-bit data in the read data transmitted through the transmission paths of the target data input/output pin; and
each first selector is configured to: in the test mode, transmit compressed data of a data input/output pin corresponding to the first selector to the target data input/output pin, and in the operating mode, transmit, to the target data input/output pin, 1-bit data in the read data transmitted through the transmission paths of the target data input/output pin.

7. The memory according to claim 5, comprising:
a first buffer, an input terminal thereof being connected to the data input/output selector, and the first buffer being configured to: store data output by the data input/output selector, and output, after a read command is received, the data output by the data input/output selector.

8. The memory according to claim 7, comprising:
a first parallel-to-serial conversion circuit, an input terminal thereof being connected to the first buffer, and the first parallel-to-serial conversion circuit receiving data output by the first buffer, performing parallel-to-serial conversion on the data output by the first buffer, and outputting data obtained through parallel-to-serial conversion to the target data input/output pin.

9. The memory according to claim 8, wherein in the test mode, the first parallel-to-serial conversion circuit is specifically configured to sort the plurality of pieces of compressed data in a sequence of the data input/output pins, to convert the plurality of pieces of compressed data into serial data.

10. The memory according to claim 9, wherein the plurality of data input/output pins comprise the target data input/output pin and other data input/output pins; and
the memory comprises:
a second buffer, an input terminal thereof receiving read data transmitted through transmission paths of the other data input/output pins, and the second buffer being configured to: store the read data transmitted through the transmission paths of the other data input/output pins, and output, after a read command is received, the read data transmitted through the transmission paths of the other data input/output pins.

11. The memory according to claim 10, wherein the second buffer comprises a plurality of sub-buffers, an input terminal of each sub-buffer receives read data transmitted through transmission paths of one of the other data input/output pins, and the sub-buffer is configured to: store the read data transmitted through the transmission paths of the data input/output pin corresponding to the sub-buffer, and output, after the read command is received, the read data transmitted through the transmission paths of the data input/output pin corresponding to the sub-buffer.

12. The memory according to claim 10, comprising:
a second parallel-to-serial conversion circuit, an input terminal thereof being connected to the second buffer, and the second parallel-to-serial conversion circuit receiving data output by the second buffer, performing parallel-to-serial conversion on the data output by the second buffer, and outputting data obtained through parallel-to-serial conversion to the other data input/output pins.

13. The memory according to claim 12, wherein the second parallel-to-serial conversion circuit comprises a plurality of parallel-to-serial conversion sub-circuits, an input terminal of each parallel-to-serial conversion sub-circuit is connected to one sub-buffer, and each parallel-to-serial conversion sub-circuit receives data output by the corresponding sub-buffer, performs parallel-to-serial conversion on the data output by the corresponding sub-buffer, and outputs data obtained through parallel-to-serial conversion to one of the other data input/output pins.

14. The memory according to claim 1, further comprising:
data mask pins receiving check code data, wherein the memory checks, based on the check code data, the read data transmitted through the transmission paths of the plurality of data input/output pins.

15. The memory according to claim 14, wherein the data mask pins comprise a first data mask pin and a second data mask pin, the first data mask pin receives first check code data, and the second data mask pin receives second check code data; and
the memory checks, based on the first check code data, data transmitted through transmission paths of some of the plurality of data input/output pins, and checks, based on the second check code data, data transmitted through transmission paths of the remaining data input/output pins in the plurality of data input/output pins.
